(19) United States
(12) Patent Application Publication
(10) Pub. No.: US 2026/0151806 A1
(43) Pub. Date: Jun. 4, 2026

(54) METHOD AND DEVICE FOR PROCESSING A SOLAR MODULE

(71) Applicant: SOLAR MATERIALS GMBH, Magdeburg (DE)

(72) Inventors: Jan BARGEL, Magdeburg (DE); Fridolin FRANKE, Magdeburg (DE); Jan-Philipp MAI, Magdeburg (DE)

(21) Appl. No.: 18/706,569

(22) PCT Filed: Sep. 30, 2022
(86) PCT No.: PCT/EP2022/077338

§ 371 Date: May 1, 2024

(30) Foreign Application Priority Data
Nov. 10, 2021 (DE) 10 2021 129 301.4

(51) Int. Cl. B09B 3/50; B09B 3/30; B09B 101/15

(52) U.S. Cl. CPC B09B 3/50; B09B 3/30; B09B 2101/15

(57) ABSTRACT

The invention relates to a method for processing a solar module, wherein the solar module has at least one silicon base body with a charge-doped zone, a hole-doped zone and an upper side, metallic conductor tracks on the upper side of the base body, a surface layer that is at least partially transparent to visible light, but preferably transparent to visible light, and at least one adhesive layer arranged between the surface layer and the conductor tracks, the method comprising the following steps:
a) heating the at least one adhesive layer,
b) removing the cover layer from the base body and
c) mechanically removing the conductor tracks and collecting the machined material.

The invention relates to a method for processing a solar module, wherein the solar module has at least one silicon base body with a charge-doped zone, a hole-doped zone and an upper side, metallic conductor tracks on the upper side of the base body, a cover layer that is at least partially transparent to visible light, but preferably transparent to visible light, and at least one adhesive layer arranged between the cover layer and the conductor tracks. The invention also relates to a device for conducting such a method.

Solar modules of the type mentioned above are being used in increasing numbers to generate electricity from sunlight. For example, said solar modules may be placed in small numbers on roofs of private buildings, such as residential buildings, in order to at least partially meet the electricity demand of the house on which the solar modules are mounted. This use of this kind of decentralized energy supply is increasing, for example to charge electric vehicles decentrally. However, solar modules of the type mentioned above are also used in large installations on otherwise agricultural land to generate commercial electricity and feed it into the public grid.

The disadvantage is that the solar modules only have a limited service life. Expensive raw materials are used during production of the solar modules. For example, the conductor tracks are manufactured from silver for a large number of modules. For this reason alone, there is a need for a method that recycles said raw materials and makes them available for reprocessing. However, the growing number of solar modules that reach the end of their service life and are discarded also creates a large amount of waste, which should be recycled or at least treated, particularly in view of the environmental compatibility of electricity generation, of which solar modules and the generation of electricity from sunlight are emblematic. For solar modules which contain metal components arranged on a glass substrate, JP 2014/054593 A proposes a method in which the components are mechanically removed. The glass described in said publication is capable of withstanding mechanical stress, which is precisely why these substrates are described and disclosed there. For other substrates, the only processes known thus far from the prior art use wet chemical processes, which are disadvantageous due to the high costs, the substances used, which are often harmful to the environment and/or health, and the high degree of effort involved.

The invention is therefore based on the task of proposing a method with which that the disadvantages of the prior art can be eliminated or at least reduced.

The invention solves the addressed task by way of a method of the type described above, which comprises the following steps:
a) heating the at least one adhesive layer,
b) removing the cover layer from the base body and
c) mechanically removing the conductor tracks and collecting the machined material.

One difficulty that is eliminated by the method according to the invention is that the conductor tracks of the solar modules, which are produced from the valuable raw material, are not accessible from the outside. They are located on the upper side of the base body, but are covered by the cover layer, which is fixed by the at least one adhesive layer. Heating the adhesive layer reduces its adhesive effect so that the cover layer and base body can be removed from each other afterwards. The conductor tracks arranged on the upper side of the base body are then accessible. They are now removed from the base body by mechanical removal and the removed material is collected.

Preferably, the adhesive layer is heated by means of infrared radiation and/or magnetic induction and/or by means of microwave radiation. Heating is carried out to a temperature of more than 180° C., preferably more than 200° C., especially preferably more than 230° C. and less than 400° C., preferably less than 350° C., especially preferably less than 280° C. Particularly when using infrared radiation or microwave radiation, it is advantageous to apply the radiation through the cover layer, which is preferably at least partially, but preferably fully, transparent to the respective type of radiation. Infrared radiation used for this purpose preferably has a wavelength between 1000 and 4000 nm, preferably from 1000 to 2000 nm. The preferred temperature is below 400° C. Above this temperature, pyrolysis occurs, during which toxic and environmentally harmful gases are released. This can be avoided with a temperature below 400° C. At a temperature of more than 180° C., preferably more than 200° C., acetic acid is preferably released in the adhesive layer, which creates a lubricating film between the layers connected by the adhesive layer, Le. preferably the base body and the cover layer. This causes forces of adhesion, which are applied by the adhesive layer, to decrease and the two connected elements can be separated from each other. Preferably, at least one film of ethylene vinyl acetate (EVA) is also used as an adhesive layer, which releases acetic acid when heated in the temperature range mentioned.

Once the adhesive layer has been heated to the desired temperature, either the heat source can be switched off or controlled such that the temperature is kept constant for a certain amount of time, for example 10 minutes, in order to process the solar module at this temperature. Heating is preferably done across the full surface so that the entire adhesive layer of the solar module to be processed is heated evenly. Alternatively, it is also possible to heat part of the adhesive layer and, for example, to move the heat source relative to the solar module or vice-versa. During heating, the solar module is preferably in a vacuum, le. it is subjected to a negative pressure. However, heating under normal pressure is also possible.

If electromagnetic radiation is used as a heat source, it can be introduced directly into the adhesive layer to be heated through the cover layer, which is at least partially transparent to said radiation. This is different when using magnetic induction, as the adhesive layer is generally not magnetic or cannot generally be magnetized. In this case, the magnetic induction field causes another layer of the solar module to be heated, preferably the base body, which can also be referred to as a substrate or wafer, so that it then emits heat to the adhesive layer arranged on it.

Lasers can also be used in addition or as an alternative to the heat sources mentioned, in order to heat the at least one adhesive layer.

In a preferred embodiment, the cover layer is removed from the base body by applying opposing forces, for example applying opposing tensile forces to the cover layer and the base body. In this case, the opposing tensile forces can be applied perpendicular to the upper side of the base body. For a solar module lying on a work surface, this means that the tensile forces act upwards and downwards. Negative pressure elements, such as suction elements, are preferably used for this purpose. The substrate is preferably positioned on a work surface that has openings which are then sealed by the substrate. By applying a negative pressure or a suction force to the sealed openings, a suction force and therefore a tensile force is exerted on the substrate that holds it on the work surface. Preferably at least one suction element or at least one suction pad is applied to the cover layer which is configured to apply a suction force to the cover layer, which is directed away from the work surface, i.e. it generally acts upwards. As a result, two opposing forces are applied and the cover layer is separated from the substrate.

Alternatively or additionally, at least one slide is used to apply a force to the cover layer that acts parallel to the work surface on which the substrate is arranged. The substrate is preferably held in place by the previously described suction force on the work surface. Alternatively or additionally, the work surface has an end stop, which protrudes from the work surface and rests on the substrate. The substrate rests on the end stop in such a way that a movement of the substrate, which has been caused by the force applied by the slide, is prevented and is not possible. If the slide applies a force to a first lateral surface of the cover layer, the substrate preferably rests with the opposite side on the projection.

Alternatively, the opposing tensile forces can also be applied parallel to the upper side of the base body. This results in shear forces, by means of which the two components can be separated from each other.

In a preferred embodiment, the cover layer is damaged or destroyed before the adhesive layer is heated or before the cover layer is removed from the base body. In the process, the cover layer is preferably divided into several parts by mechanical stress. For example, this can be achieved by striking the cover layer with, for example, a hammer. The cover layer is then in multiple individual parts, most of which, but preferably all of which, are still joined to the base body via the adhesive layer. The individual parts can then be removed from the base body in the ways described above.

If the cover layer and the base body are separated from each other in such a way that they are moved in parallel, few bending moments are applied to the base body in particular, on the upper side of which the conductor tracks are located, so that the risk of the base body breaking is reduced. This has the advantage of mechanically removing the conductor tracks from the base body, which is all the easier the less mechanically damaged the base body is.

Preferably, before removing the cover layer, the cover layer is damaged by means of a tool, preferably a spatula, scraper, knife or wire, the tool preferably being inserted between the cover layer and the base body. Contrary to what happens with the base body, which is preferably undamaged and bears no cracks after the cover surface has been removed, the cover layer is completely damaged in order to be able to remove individual parts of the cover layer more easily.

Preferably, the at least one adhesive layer is also at least partially, but preferably fully, removed when the cover layer is removed. This means that as few sections of the adhesive layer as possible remain on the upper side of the base body and thus on the conductor tracks. These parts would be collected with the removed material during the mechanical removal of the conductor tracks. They would then potentially have to be separated from the material of the conductor tracks in a complex and costly manner.

The adhesive layer is therefore preferably at least partially, but preferably fully, removed once the cover layer has been removed. In this case, it may be advantageous to re-heat the remaining sections of the adhesive layer if the adhesive layer is no longer warm enough.

Particularly preferably, a mechanical tool, such as a wire, spatula, scraper, blade, knife or brush, is used for removing the at least one adhesive layer after removing the cover layer.

Preferably, the conductor tracks are removed by brushing, milling, planing, shaping, scraping, chiseling, broaching, blasting and/or grinding. Removal can be done using a geometrically defined or geometrically indeterminate cutting edge. The material to be removed can also be removed using tension brushes, for example round brushes, disk brushes, brushes, roller brushes, hand brushes and/or strip brushes. The brushes can be made of iron, plastic, brass or another material or material mix. The bristle diameter and bristle length may vary. The brushes can rotate, oscillate or be moved linearly or eccentrically. In a preferred embodiment, a rotating roller brush with steel wire is used, which rotates at 2000-8000 rotations per minute.

The brush can work across the whole surface or in sections and can be force-controlled and/or path-controlled.

In the case of milling, a face cutter is preferably used where the tool axis is orthogonal to the surface to be removed. For other tools, such as blades or knives, tools or blades made of steel, cubic crystalline boron nitride (CBN), aluminium oxide ceramic, polycrystalline diamond (PCD), silicon nitride ceramic, high-speed steel (HSS) are preferably used. Coated carbides, tungsten carbide-based carbides or fine-grain carbides can also be used as materials for these tools. The blade can be oriented to the conductor tracks at different angles, wherein a 45° angle is advantageous. The position of the knife may vary depending on the grind of the blade. The blade can oscillate and/or move linearly and can be, for example, force-controlled and/or path-controlled. Removal can be done across the entire surface or in sections. At least one blade is used.

Pendulum grinding is the preferred method for grinding with rotating tools. The grinding wheel is preferably a CBN wheel or a diamond grinding wheel. If belt grinding is deployed, the belt is preferably oriented to be parallel to the cover layer to be machined. The belt edge can also be oriented to be parallel to the conductor tracks. It can be removed across the entire surface or in sections.

The removed material is collected. Preferably, it is sucked up and collected in a container. For this purpose, it is advantageous if the tool used for removal is already inside a box or bell, so that the removed dust can be collected as easily as possible. The material can be collected with an air flow or a liquid flow, for example composed of water or an oil. However, preferably no liquid is used as the removed chips or dust have to be subsequently dried.

The invention solves the task addressed by way of a device for carrying out a method described here which comprises at least one heating device for heating the at least one adhesive layer, at least one traction device for exerting a tensile force, a mechanical removal device and a collection device. Preferably, the traction device has at least one, preferably several vacuum grippers and/or at least one, preferably several Bernoulli grips.

In a preferred embodiment, the device also has an electric control unit and the removal device has at least one mechanical tool, wherein the electric control unit is configured to control at least one operating parameter of the at least one mechanical tool. The at least one operating parameter is preferably a contact pressure, a path or a force. The electric control unit is preferably an electronic data processing device, which is preferably part of the device. However, it is also sufficient if the electronic data processing device is not part of the device, but the device communicates with the electronic data processing device via a communication device.

In the following, an embodiment example of the invention will be explained in more detail with the aid of the accompanying figures. They show:

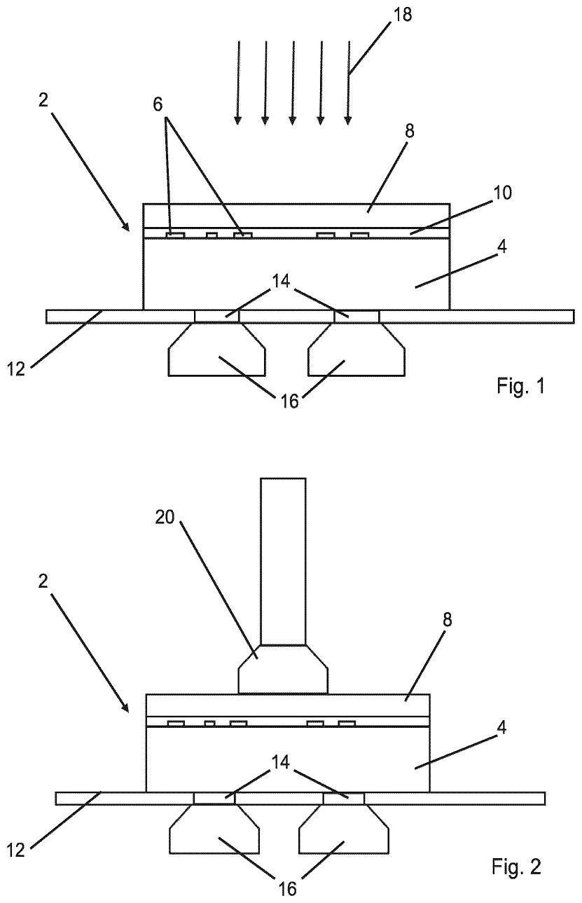

FIGS. 1 to 4 process steps in a method according to a first embodiment example of the present invention.

FIG. 1 depicts a solar module 2 that comprises a substrate 4 on which conductor tracks 6 are arranged. The conductor tracks 6 are covered by a cover layer 8, which is fixed to the substrate 4 via an adhesive layer 10 that surrounds the conductor tracks 6. The solar module 2 is located on a work surface 12 which, in the embodiment example shown, comprises two openings 14, which are sealed by the substrate 4 arranged thereon. A suction device 16, which is only depicted schematically, is arranged below each of the openings 14. The suction devices 16 are configured to apply a negative pressure to the openings 14 and to thus exert a suction force on the substrate 4 of the solar module 2. In the process step according to FIG. 1, the solar module 2 is heated from above by means of electromagnetic radiation 18 created, for example, by a laser. Since the cover layer 8 is at least partially transparent, but preferably fully transparent, to visible light, the electromagnetic radiation 18 passes through the cover layer 8 and heats the adhesive layer 10.

FIG. 2 illustrates a subsequent process step. The solar module 2 is still on the work surface 12. The substrate 4 is still held on the work surface 12 by the suction devices 16. In this process step, a suction pad acts on the cover layer 8 and exerts an upward-acting force on the cover layer 8. This means that two opposing forces are acting between the substrate 4 and the cover layer 8, thus removing the cover surface 8 from the substrate 4.

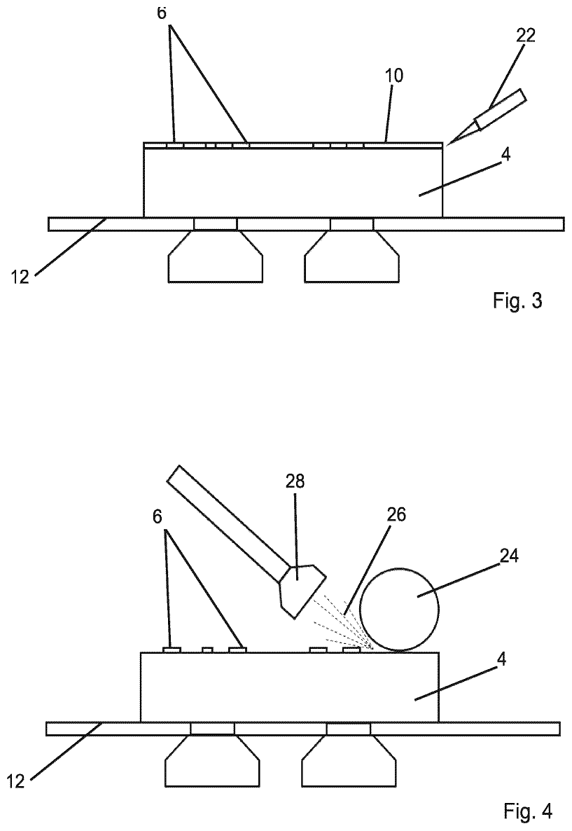

FIG. 3 shows the situation in the next process step. The substrate 4 continues to be held on the work surface 12 and the conductor tracks 6 are located on the side of the substrate 4 facing away from the work surface 12. Said conductor tracks are still at least partially surrounded by the adhesive layer 10 after the cover layer 8 has been removed from the substrate 4. This is illustrated in FIG. 3 in that the adhesive layer 10 is shown to be significantly thinner when compared to the adhesive layer 10 in FIGS. 1 and 2. It is not a realistic depiction. When the cover layer 8 is removed from the substrate 4, part of the adhesive layer 10 is removed along with it. However, depending on the state of heating and adhesive properties, this occurs irregularly and is in no way homogeneous. There may well be areas in which the adhesive layer 10 has been completely removed. There may well be areas in which the conductor tracks 6 are still fully surrounded by the adhesive layer 10. The remaining part of the adhesive layer 10, which is shown in FIG. 3, is removed in this process step by a tool 22, which may be a spatula or a knife, for example.

In FIG. 4 the adhesive layer 10 has been completely removed from the upper side of the substrate 4. The conductor tracks 6 are still arranged on the upper side of the substrate 4. This is also a schematic depiction, not a realistic depiction. Remains of the adhesive layer 10 are also remain on the upper surface of the substrate 4 in this process step. The conductor tracks 6 are removed from the substrate 4 by way of a brush 24 which, in the embodiment example shown, is at an offset in the clockwise direction during rotation and moves relative to the upper surface of the substrate 4. Material 26 is thrown up and then collected by a suction cup 28 and fed for further processing.

### REFERENCE LIST

2 solar module
4 substrate
6 conductor track
8 cover layer
10 adhesive layer
12 work surface
14 opening
16 suction device
18 electromagnetic radiation
20 suction pad
22 tool
24 brush
26 material
28 suction cup

1. A method for processing a solar module comprising
at least one silicon base body with a charge-doped zone, a hole-doped zone, and an upper side,
metallic conductor tracks on the upper side of the at least one silicon base body,
a cover layer that is at least partially transparent to visible light, and
at least one adhesive layer arranged between the cover layer and the metallic conductor tracks,
the method comprising the following steps:
a) heating the at least one adhesive layer,
b) removing the cover layer from the at least one silicon base body, and
c) mechanically removing the metallic conductor tracks and collecting a machined material.

2. The method according to claim 1, wherein the adhesive layer is heated by infrared radiation and/or magnetic induction and/or microwave radiation to a temperature of more than 180° C.

3. The method according to claim 1 wherein the cover layer is removed from the at least one silicon base body by applying forces acting in an opposite direction from the cover layer and the at least one silicon base body.

4. The method according to claim 1 further comprising, prior to removing the cover layer, damaging the cover layer.

5. The method according to claim 1 wherein the at least one adhesive layer is also at least partially removed when the cover layer is removed.

6. The method according to claim 5, wherein the at least one adhesive layer is removed after the cover layer has been removed.

7. The method according to claim 6, wherein a mechanical tool is used for removing the at least one adhesive layer.

8. The method according to claim 1 wherein the metallic conductor tracks are removed by brushing, milling, planing, shaping, scraping, chiseling, broaching, blasting and/or grinding.

9. The method according to claim 1 wherein the machined material is sucked up and collected in a container.

10. A device for carrying out a method according to claim 1, wherein the device comprises at least one heating device for heating the at least one adhesive layer, at least one traction device for exerting a tensile force, a mechanical removal device, and a collection device.

11. The device according to claim 10, wherein the traction device comprises at least one vacuum gripper.

12. The device according to claim 10 wherein the device further comprises an electric control unit, and wherein the mechanical removal device has at least one mechanical tool, wherein the electric control unit is configured to control at least one operating parameter of the at least one mechanical tool.

13. The device according to claim 12, wherein the at least one operating parameter is a contact pressure, a path, or a force.

14. The method according to claim 4 wherein damaging the cover layer is accomplished by inserting a toll between the cover layer and the at least one silicon base body.

15. The method of claim 2 wherein the temperature is more than 200° C. and less than 280° C.
